(19) United States
(12) Patent Application Publication
(10) Pub. No.: US 2015/0361551 A1
(43) Pub. Date: Dec. 17, 2015

(54) PROTECTIVE COATINGS FOR ELECTRONIC DEVICES AND ATOMIC LAYER DEPOSITION PROCESSES FOR FORMING THE PROTECTIVE COATINGS

(71) Applicant: HZO, Inc., draper, UT (US)

(72) Inventors: Tining Su, Draper, UT (US); Sean Owen Clancy, Draper, UT (US); Chien-Lan Hsueh, Draper, UT (US); Yang Yun, Draper, UT (US); Liulei Cao, Salt Lake City, UT (US)

(21) Appl. No.: 14/740,193

(22) Filed: Jun. 15, 2015

Related U.S. Application Data
(60) Provisional application No. 62/011,788, filed on Jun. 13, 2014.

(51) Int. Cl. C23C 16/455; C23C 16/50; C23C 16/48

(52) U.S. Cl. CPC C23C 16/45544; C23C 16/48; C23C 16/50

(57) ABSTRACT

A protective coating for an electronic device, such as a coating that is substantially impermeable to moisture and oxygen, comprises an ultra-thin film comprising a plurality of sub-layers formed by atomic layer deposition (ALD) processes. Low temperature ALD processes may be used to form the sub-layers of the protective coating. The density of the protective film may be enhanced with energy, to which the protective coating or sub-layers thereof may be exposed during deposition or intermittently during the deposition process. ALD apparatuses that are equipped to perform the disclosed processes are also disclosed, as are electronic devices that include the disclosed protective coatings.

### CROSS-REFERENCE TO RELATED APPLICATION

A claim for priority to the Jun. 13, 2014, filing date of U.S. Provisional Patent Application 62/011,788, titled PROTECTIVE COATINGS FOR ELECTRONIC DEVICES AND ATOMIC LAYER DEPOSITION PROCESSES FOR FORMING THE PROTECTIVE COATINGS (“the '788 Provisional Application) is hereby made pursuant to 35 U.S.C. §119(e). The entire disclosure of the '788 Provisional Application is hereby incorporated by reference.

### TECHNICAL FIELD

This disclosure relates generally to protective coatings, including moisture-resistant coatings, for electronic device assemblies and, more specifically, to ultra-thin moisture-resistant coatings that are impermeable to moisture and to oxygen. More specifically, this disclosure relates to metal oxide coatings that may be formed by low temperature processes. In addition, this disclosure relates to processes for forming ultra-thin moisture resistant coatings on electronic device assemblies at low temperatures. This disclosure also relates to electronic device assemblies that are at least partially coated with ultra-thin moisture-resistant coatings.

### SUMMARY

In one aspect, this disclosure relates to ultra-thin protective coatings for electronic device assemblies. As used herein, “ultra-thin” refers to thickness of 250 nm and less, including, but not limited to, thicknesses of 200 nm or less, 100 nm or less, 50 nm or less, 30 nm or less and ranges defined by any of these values. The term “ultra-thin” also refers to films defined by atomic layer deposition (ALD) processes.

An “electronic device assembly” includes an assembly of electronic device components. One example of an electronic device assembly includes a printed circuit board and electrical components (e.g., semiconductor devices, etc.) that have been electrically coupled thereto; for example, by surface mount processes. As another example, an electronic device assembly may include an assembly of electronic components, such as a printed circuit board and one or more electronic components that are electrically coupled to the printed circuit board, but not carried by the printed circuit board. In yet another example, an electronic device assembly may comprise a partially or fully assembled electronic device (e.g., a portable electronic device, an electronic device that is configured for use in which moisture is likely to be present, a medical electronic device, etc.), which may include at least part of a housing.

A protective coating according to this disclosure may be made by a low temperature process. The phrase “low temperature,” as used herein, refers to temperatures to which an assembled electronic device or an electronic device assembly can be safely exposed. Some specific, but non-limiting examples of “low temperatures” include temperatures of about 150° C. and below, about 100° C. and below, about 75° C. and below, about 50° C. and below and room temperature (e.g., about 25° C., about 23° C. to about 27° C., etc.).

The protective materials applied to surfaces of an electronic device may impart at least a portion of the electronic device with moisture resistance. As used herein, the term “protective coating” includes moisture resistant coatings or films, as well as other coatings or films that protect various parts of an electronic assembly from moisture and/or other external influences. While the term “moisture resistant coating” is used throughout this disclosure, in many, if not all, circumstances, a moisture resistant coating may comprise or be substituted with a protective coating that protects coated components and/or features from other external influences. The term “moisture resistant” refers to the ability of a coating to prevent exposure of a coated element or feature to moisture. A moisture resistant coating may resist wetting or penetration by one or more types of moisture, or it may be impermeable or substantially impermeable to one or more types of moisture. A moisture resistant coating may repel one or more types of moisture. In some embodiments, a moisture resistant coating may be impermeable to, substantially impermeable to or repel water, an aqueous solution (e.g., salt solutions, acidic solutions, basic solutions, drinks, etc.) or vapors of water or other aqueous materials (e.g., humidity, fogs, mists, etc.), wetness, etc.). Use of the term “moisture resistant” to modify the term “coating” should not be considered to limit the scope of materials the coating protects against. The term “moisture resistant” may also refer to the ability of a coating to restrict permeation of or repel organic liquids or vapors (e.g., organic solvents, other organic materials in liquid or vapor form, etc.), as well as a variety of other substances or conditions that might pose a threat to an electronic device or its components.

A protective coating according to this disclosure may comprise any of a variety of suitable materials. Without limitation, a protective coating may comprise an inorganic material, an organic material or a composite material (i.e., a plurality of different materials; e.g., a combination of organic material(s) and inorganic material(s), a plurality of different inorganic materials, etc.).

In embodiments where a protective coating according to this disclosure includes at least one inorganic material, the inorganic material may comprise a metal oxide. The protective coating may be formed from a material that may be deposited or otherwise formed by a low temperature process. The protective coating may be ultra-thin; accordingly, the material from which the protective layer is formed may be capable of being deposited or otherwise formed by a process that may be used to form an ultra-thin film. In various embodiments, the protective coating may comprise aluminum oxide (Al₂O₃), or alumina, titanium oxide (TiO₂), hafnium oxide (HfO₂), zirconium oxide (ZrO₂), silicon oxide (SiOₓ) or a variety of other materials. Other specific examples of inorganic materials that may be included in a protective coating according to this disclosure are, without limitation, nitrides, silicates and other materials that provide suitable properties (e.g., impermeability to moisture, hardness, corrosion resistance, etc.).

A protective coating according to this disclosure may include a plurality of sub-layers. In some embodiments, the sub-layers of a protective coating may all comprise the same material. In other embodiments, the protective coating may include a plurality of different materials. As an example of such an embodiment, one or more lower sub-layers of a protective coating may comprise materials that adhere well to one or materials of a substrate (e.g., one or more features or components of an electronic device assembly, etc.) and to a material from which a successive sub-layer is formed. The density of a protective coating and, thus, of sub-layers thereof, may increase from one side of the protective coating (e.g., its bottom, etc.) to the opposite side of the protective coating (e.g., its top, or outer surface, etc.).

In another aspect, various embodiments of methods for forming protective coatings are disclosed. Such a method may include use of atomic layer deposition (ALD) processes. In an ALD process, a substrate (e.g., an electronic device assembly, etc.) is introduced into a reaction chamber of ALD equipment. Precursor materials may be introduced into the reaction chamber, and conditions may be created within the reaction chamber that will enable the precursor materials or reactive species formed from the precursor materials to adsorb to a surface of the substrate and to react on the surface of the substrate. The reaction may be carried out at temperatures that will not damage the substrate. In some embodiments, the reaction may occur at a low temperature (e.g., a temperature of about 150° C. and below, about 100° C. and below, about 75° C. and below, about 50° C. and below and room temperature (e.g., about 25° C., about 23° C. to about 27° C., etc.). A thickness of the layer or film of material that is formed on the substrate, which may comprise a sub-layer of a multi-layer protective film, may be about the same as a distance across one atom forming the material or as a distance across one molecule of the material. The ALD process may be repeated any number of times until a protective coating with desired characteristics (e.g., a desired number of sub-layers; with different sub-layers that comprise a desired sequence of different materials, with sub-layers that have different properties (e.g., porosities, densities, etc.) from one another, etc.).

An ALD process according to this disclosure may also include application of energy to a protective coating or one or more sub-layers of the protective coating. In some embodiments, energy may also be applied to a material that is used to form a protective coating and/or to a substrate upon which a protective coating is being formed. Without limitation, the energy may comprise electromagnetic radiation. In some embodiments, the electromagnetic radiation may comprise ultraviolet (UV) radiation (e.g., radiation having a wavelength of about 100 nm to about 310 nm, radiation having a wavelength of about 100 nm to about 250 nm, radiation having a wavelength of about 100 nm to about 200 nm, radiation having a wavelength of about 100 nm to about 150 nm, etc.), which may be applied to all or part of a protective coating. In other embodiments, energy may be applied in the form of infrared (IR) radiation. Other non-limiting examples of the types of energy that may be applied to a protective coating, to one or more sub-layers of a protective coating, to materials that are being used to form a protective coating or a sub-layer thereof and/or to a substrate upon which a protective coating is formed include plasmas and ultrasonic energy.

UV, IR and other wavelengths (or bandwidths) of electromagnetic radiation, as well as other types of energy, may facilitate the removal of contaminants (e.g., byproducts of a reaction, such as carbon dioxide (CO₂), water (H₂O), etc.; unreacted reactants; contaminants; etc.) from a layer or film or from a series of layers or films of material that have been formed by ALD processes. By removing contaminants, the incidence of defects in a coating may be reduced. For example, removal of contaminants during a reaction may prevent the formation of pores or other defects in a layer as that layer is formed. Removal of contaminants following the deposition of a layer may minimize the sizes of defects that are present in layers that have already been formed, reverse at least some defects in the layer or layers that have already been formed and/or prevent the formation of pores or other defects in one or more subsequently formed layers. Thus, applying energy to all or part(s) of a protective coating, to one or more sub-layers of a protective coating, to the reactants that are used to form the protective coating and/or to the substrate on which the protective coating is formed may enable the use of low temperature processes while providing a coating or sub-layers of a coating with properties that are comparable to similar films or laminates formed by conventional high temperature processes.

In some embodiments, energy may be applied during the deposition of each layer or sub-layer of a protective coating. In other embodiments, energy may be applied to each layer or sub-layer of a protective coating just after that layer or sub-layer has been formed. Alternatively, energy may be applied after a predetermined number of sub-layers have been formed by ALD processes. As another alternative, energy may be applied after a specific type of material has been deposited or a material having a specific property (e.g., porosity, density, etc.) has been deposited, and before a different material or the same material with a different specific property is deposited. Optionally, a protective coating may be exposed to energy after deposition of the protective coating has been completed.

Other aspects, as well as features and advantages of various aspects, of the disclosed subject matter will become apparent to those of ordinary skill in the art through consideration of the ensuing description and the appended claims.

### DETAILED DESCRIPTION

An ALD process may be used to apply a protective layer to a plurality of components of an electronic device assembly. The ALD process may be incorporated into an assembly process (e.g., after surface mount processing; as part of an assembly line; off-line before or after electronic components with a printed circuit board; etc.) while manufacturing an electronic device, as disclosed by U.S. Patent Application Publication US 2013/0286567 A2 of HZO, Inc., the entire disclosure of which is hereby incorporated herein. Alternatively, the ALD process of this disclosure may be used to apply a protective coating to an electronic device assembly as part of a refurbishing process or a remanufacturing process, as disclosed by U.S. Patent Application Publications US 2013/0335898 A1 and US 2014/0160650 A1 of HZO, Inc., the entire disclosures of both of which are hereby incorporated herein. An electronic device produced by such a process may be configured in the manner disclosed by U.S. Patent Application Publication 2013/0176700 A1 of HZO, Inc., the entire disclosure of which is hereby incorporated by reference.

The process of applying a protective coating to an electronic device may include introducing the electronic device assembly into a deposition chamber, or a reaction chamber, of an ALD apparatus. The electronic device assembly may include a plurality of electronic components, as well as electrical coupling elements that enable the electronic components to communicate with one another and/or function together. In some embodiments, the electronic device assembly may include a printed circuit board (PCB) and one or more electronic components that have been assembled with the PCB. In other embodiments, the electronic device assembly may include two or more electronic components, at least one electronic coupling element and at least a portion of an outer housing of an electronic device. Other embodiments of electronic device assemblies may include an electronic device with a portion of its housing removed to expose portions of two or more electronic components that are typically located within an interior of the electronic device. In any event, locations or areas of the electronic device assembly that are to be coated with the protective material are exposed when the electronic device assembly resides within the reaction chamber.

With one or more electronic device assemblies present within a reaction chamber of an ALD apparatus, each electronic device assembly may be subjected to decontamination processing. Without limitation, a plasma of an inert material or a substantially inert material (e.g., argon (Ar), nitrogen (N), etc.) may be used to at least partially decontaminate each electronic device assembly within the reaction chamber. Such a treatment may also effectively purge the reaction chamber. As another option, each electronic device assembly within the reaction chamber, as well as surfaces of the reaction chamber, may be subjected to electromagnetic radiation (e.g., UV radiation, etc.) that may remove contaminants (e.g., CO₂, H₂O, CₓH_{y}, residual precursor material(s), or reactants, etc.) from the treated surfaces.

When application of a protective coating to exposed surfaces of the electronic device assembly is desired, known precursor materials may be used under low temperature process conditions to form atomic layers of one or more desired materials. In a specific embodiment, trimethyl aluminum (TMA) (Al(CH₃)₃) and water molecules (H₂O) may be used as precursor materials that will react to deposit aluminum oxide (Al₂O₃), or alumina, onto the electronic device assembly. An alternative reaction for depositing aluminum oxide includes TMA and ozone (O₃) as precursor materials, or reactants. As alternatives to depositing aluminum oxide, other metal oxides, such as TiO₂, HfO₂, SiO₂ and ZrO₂ may be deposited using known chemistries. Of course, a variety of other types of materials, including, without limitation, other inorganic materials, organic materials and composite materials (which may include different types of inorganic materials, different types of organic materials and/or both organic and inorganic materials) may be used to form one or more sub-layers or a protective coating according to this disclosure.

The reactants may be introduced into the reaction chamber in a suitable manner and subjected to a plasma at a low temperature (e.g., about 150° C. or less, about 100° C. or less, about 75° C. or less, about 50° C. or less, at room temperature (e.g., about 25° C., about 23° C. to about 27° C., etc.), etc.).

In addition, the electronic device assembly and any material layers deposited therein may be subjected to energy in conjunction with the deposition process. In more specific embodiments, the electronic device assembly and any material layers thereon may be subjected to electromagnetic radiation, such as UV radiation, which includes wavelengths of electromagnetic radiation from about 100 nm to about 310 nm, as well as a variety of sub-ranges including and between those wavelengths (e.g., radiation having a wavelength of about 100 nm to about 250 nm, radiation having a wavelength of about 100 nm to about 200 nm, radiation having a wavelength of about 100 nm to about 150 nm, etc.). Other wavelengths of electromagnetic radiation may be used instead of UV radiation. Alternative types of energy that may be applied in conjunction with the deposition of a material layer include, but are not limited to, exposure of a material layer to a plasma and/or ultrasonic energy. Application of energy may be effected as material of a protective coating (e.g., aluminum oxide, another inorganic material, an organic material, a composite material, etc.) is deposited onto an electronic device assembly or after one or more material layers have been formed on the electronic device assembly.

Since each cycle of an ALD process results in a film having a thickness that is about the same as a distance across one atom (e.g., about the distance across an aluminum atom, etc.) or as a distance across one molecule (e.g., about the distance across a molecule of aluminum oxide, etc.), the above-described process may be repeated several times until a protective layer having a desired thickness has been formed. As an example, when a protective layer comprises aluminum oxide, it may take about three hundred (300) ALD cycles to form a protective coating that has a thickness of about 30 nm. While a variety of protective coating thicknesses are within the scope of this disclosure, some specific embodiments include thicknesses of 10 nm, 50 nm, 100 nm, 200 nm, 250 nm and 500 nm.

A density gradient may be present through the thickness of such a multi-layer structure protective coating regardless of whether the layers comprise the same material(s) as one another or different materials from one another. In some embodiments, a density of the protective coating may increase from its lower sub-layers to sub-layers located closer to an outer surface of the protective coating. For example, the lower sub-layers may include some pores or voids, intermediate sub-layers may include fewer pores or voids and outer sub-layers may include even fewer pores or voids. Alternatively, the density gradient may be reversed, with the lower sub-layers (e.g., those closest to and/or attached to the substrate, etc.) having fewer pores or voids and the sub-layers that are more distant from the substrate having a greater number of pores or voids. Other types or arrangements of density gradients are also within the scope of this disclosure.

In embodiments where a protective layer includes two or more different materials, one or more cycles of an ALD process with a first set of reactants may be performed to form a corresponding number of sub-layers of a first material, the reaction chamber may be purged, and then one or more cycles of an ALD process with a second set of reactants may performed to form a corresponding number of sub-layers of a second material. If sub-layers of other materials are to be added to the protective coating, the reaction chamber may again be purged before further ALD processing is performed with a new set of reactants, or a new chemistry.

A 10 nm thick protective coating comprising ALD-deposited aluminum oxide and deposited in accordance with this disclosure may have a water vapor transfer rate (WVTR) of about 1.0×10⁻⁵ g/m² per day and an oxygen transfer rate (OTR) of about 5.0×10⁻³ (cc×mm)/(m²×day×atm). Similar WVTRs may be achieved with protective coatings formed from other inorganic materials.

Despite the high impermeability values that may be achieved with a protective coating according to this disclosure, electrical connections may be readily made through such a protective coating (e.g., by conventional electrical connection techniques, by way of friction generated through standard interference-type electrical connections (e.g., by way of plug-type electrical connectors, etc.), etc.). When electrical connections are made through an aluminum oxide protective coating having a thickness of about 30 nm, a test device (a PCB carrying a power supply and a plurality of light-emitting diodes (LEDs)) will continue to operate for two hours to five hours when submersed in water. In contrast, an unprotected test device failed within one second of submersion, while electrical connections could not be made through Parylene layers having average thicknesses of 2 μm and 7 μm.

An electronic device assembly that has been subjected to processing in accordance with teachings of this disclosure may include an ultra-thin layer of a protective material, such as aluminum oxide, titanium oxide, hafnium oxide, silicon oxide, another inorganic material (e.g., a nitride, a silicate, etc.), an organic material or a composite material (e.g., of different inorganic materials, of different organic materials, of a combination of one or more inorganic materials and one or more organic materials, etc.). The ultra-thin layer of protective material may coat portions of two or more electronic components, as well as electrical coupling elements between the two or more electronic components. The ultra-thin layer of protective material may be substantially free of contaminants (e.g., contaminants, residual reactants, by-products of the process by which the ultra-thin layer of protective material was formed, etc.). In addition, the ultra-thin layer of protective material may be substantially free of pores, voids or other imperfections that diminish its impermeability to moisture and oxygen. In addition to including an ultra-thin layer of protective material with these features, the electronic device assembly may be free of thermally induced defects or damage, such as those that may have otherwise been present if the electronic device assembly were exposed to elevated temperatures (e.g., temperatures above about 150° C., etc.).

While the preceding disclosure focuses on the application of materials to electronic device assemblies, it should be understood that the disclosed processes may be used to apply materials to a variety of different types of substrates at low temperatures.

From the foregoing, it should be apparent that the disclosed processes may be effected with an ALD apparatus that includes at least one source of energy within the reaction chamber of the ALD apparatus or outside of the reaction chamber. In embodiments where UV radiation is employed as the energy, each source of electromagnetic radiation may comprise a UV lamp, such as a deuterium lamp. The source(s) of energy may be oriented to direct energy onto a substrate within the reaction chamber, onto a material layer that has been formed on the substrate and/or onto any other desired surfaces within the reaction chamber, including surfaces of the reaction chamber and components of the ALD apparatus within the reaction chamber.

Although the foregoing disclosure provides many specifics, these should not be construed as limiting the scope of any of the ensuing claims. Other embodiments may be devised which do not depart from the scopes of the claims. Features from different embodiments may be employed in combination. The scope of each claim is, therefore, indicated and limited only by its plain language and the full scope of available legal equivalents to its elements.

What is claimed:

1. An atomic layer deposition process, comprising:
introducing a substrate into a reaction chamber of an atomic layer deposition (ALD) apparatus;
introducing reactants into the reaction chamber at a temperature of 150° C. or less to enable a product to be formed as a film on the substrate; and
with the substrate in the reaction chamber, exposing the substrate or the film to energy.

2. The atomic layer deposition process of claim 1, wherein introducing the substrate comprises introducing an electronic device assembly into the reaction chamber.

3. The atomic layer deposition process of claim 1, wherein introducing reactants comprises introducing reactants that will form a product comprising an inorganic material on the substrate.

4. The atomic layer deposition process of claim 3, wherein introducing reactants comprises introducing reactants that will form a product comprising a metal oxide on the substrate.

5. The atomic layer deposition process of claim 4, wherein introducing reactants comprises introducing reactants that will form aluminum oxide, titanium oxide, hafnium oxide or silicon oxide on the substrate.

6. The atomic layer deposition process of claim 1, wherein introducing reactants comprises introducing reactants that will form a product comprising an organic material on the substrate.

7. The atomic layer deposition process of claim 1, wherein exposing the substrate or the film to energy comprises exposing the substrate or the film to electromagnetic radiation.

8. The atomic layer deposition process of claim 7, wherein exposing the substrate or the film to electromagnetic radiation comprises exposing the substrate or the film to ultraviolet radiation and/or to infrared radiation.

9. The atomic layer deposition process of claim 1, wherein exposing the substrate or the film to energy comprises exposing the substrate or the film to a plasma.

10. The atomic layer deposition process of claim 1, wherein exposing the substrate or the film to energy comprises exposing the substrate or the film to ultrasonic energy.

11. The atomic layer deposition process of claim 1, wherein exposing the substrate or the film to energy comprises exposing the substrate or the film to energy while the product is formed.

12. The atomic layer deposition process of claim 1, wherein exposing the substrate or the film to energy comprises exposing the film to energy after the film has been formed on the substrate.

13. The atomic layer deposition process of claim 12, wherein exposing the film to energy comprises exposing each sub-layer of a film comprising a plurality of sub-layers to energy after that sub-layer has been formed and before a subsequent sub-layer of the plurality of sub-layers is formed.

14. The atomic layer deposition process of claim 1, wherein exposing the substrate or the film to energy comprises removing contaminants from the product or the film.

15. The atomic layer deposition process of claim 1, comprising exposing the reaction chamber and the substrate to energy before and/or after introducing reactants into the reaction chamber.

16. The atomic layer deposition process of claim 1, wherein introducing reactants into the reaction chamber comprises introducing reactants into the reaction chamber at room temperature.

17. An atomic layer deposition process, comprising:
introducing an electronic device assembly into a reaction chamber of an atomic layer deposition (ALD) apparatus;
introducing tri-methyl aluminum (TMA) and at least one other reactant into the reaction chamber at a temperature of 150° C. or less to form aluminum oxide (Al₂O₃) on exposed areas of the electronic device assembly; and
exposing the electronic device assembly, the reactants, the Al₂O₃ and reaction byproducts to ultraviolet (UV) radiation to remove contaminants from the Al₂O₃.

18. An electronic device, comprising:
an electronic device assembly including a plurality of electronic components and electrical coupling elements between the plurality of electronic components, the electronic device assembly lacking thermally induced defects or damage; and
an ultra-thin protective coating comprising a plurality of superimposed atomic layers on at least portions of at least two electronic components and each electrical coupling element therebetween.

19. The electronic device of claim 18, wherein the ultra-thin protective coating comprises an inorganic material.

20. The electronic device of claim 19, wherein the inorganic material of the ultra-thin protective coating comprises a metal oxide.

21. The electronic device of claim 19, wherein the ultra-thin protective coating further comprises an organic material.

22. The electronic device of claim 18, wherein the ultra-thin protective coating substantially lacks contaminants and imperfections.

23. The electronic device of claim 18, wherein the ultra-thin protective coating includes a plurality of different materials, with at least a first sub-layer comprising a first material and at least a second sub-layer comprising a second material.

24. The electronic device of claim 23, wherein the plurality of different materials provide a material concentration gradient through a thickness of the ultra-thin protective coating.

25. The electronic device of claim 23, wherein the first material facilitates adhesion between the substrate and the second material.

26. The electronic device of claim 25, wherein the second material imparts the ultra-thin protective coating with environmental protection including water-resistance and/or corrosion-resistance.

27. The electronic device of claim 18, comprising a density gradient through a thickness of the ultra-thin protective coating.

28. An atomic layer deposition apparatus, comprising a reaction chamber and a source of energy oriented to direct energy onto a substrate positioned within the reaction chamber.

29. The atomic layer deposition apparatus of claim 28, wherein the source of energy comprises a source of UV radiation.

30. The atomic layer deposition apparatus of claim 28, wherein the source of energy is oriented to direct energy onto a material layer that has been deposited onto the substrate.
